(19) United States
(12) Patent Application Publication
(10) Pub. No.: US 2011/0249533 A1
(43) Pub. Date: Oct. 13, 2011

(54) GLASS SUBSTRATE POLISHING METHOD, PACKAGE MANUFACTURING METHOD, PIEZOELECTRIC VIBRATOR, OSCILLATOR, ELECTRONIC DEVICE AND RADIO TIMEPIECE

(76) Inventors: Youichi Fujihira, Chiba-shi (JP); Kazuyoshi Sugama, Chiba-shi (JP)

(21) Appl. No.: 13/163,069

(22) Filed: Jun. 17, 2011

Related U.S. Application Data
(63) Continuation of application No. PCT/JP2009/053331, filed on Feb. 25, 2009.

(51) Int. Cl. G04C 11/02; H03B 5/36; H01L 41/22; H01L 41/053; B24B 1/00; H05K 3/00

(52) U.S. Cl. 368/47; 451/41; 29/829; 29/25.35; 310/344; 331/158

(57) ABSTRACT

A glass substrate polishing method for polishing a glass substrate using a polishing device is provided. The glass substrate polishing method is characterized in that the polishing device includes a surface plate that is rotationally driven around a first central axis, a plate that is rotatable around a second central axis eccentric from the first central axis and presses the glass substrate toward the surface plate, and a work holder that is formed on the plate and restricts movement of the glass substrate in a surface direction while holding the glass substrate in a state in which a central axis of the glass substrate is eccentric from the second central axis. The glass substrate is polished by rotating the surface plate while the glass substrate is rotatably held in the work holder in a state in which an abrasive is interposed between the glass substrate and the surface plate.

### RELATED APPLICATIONS

This application is a continuation of PCT/JP2009/053331 filed on Feb. 25, 2009. The entire content of this application is incorporated herein by reference.

### BACKGROUND OF THE INVENTION

1. Field of the Invention

The present invention relates to a glass substrate polishing method, a package manufacturing method, a piezoelectric vibrator, an oscillator, an electronic device and a radio timepiece.

2. Description of the Related Art

In recent years, mobile telephones and portable information terminal devices employ a piezoelectric vibrator that uses crystal or the like as a time source, a timing source of control signals or the like, and a reference signal source etc. Various examples of this type of piezoelectric vibrator are known. One known example is a surface mount device (SMD) type piezoelectric vibrator. This type of piezoelectric vibrator includes, for example, a base substrate (a first substrate) and a lid substrate that are bonded to each other, a cavity that is formed between the two substrates, and a piezoelectric vibrating reed (an electronic component) that is housed in the cavity in an airtight sealed state.

This type of piezoelectric vibrator has a two-layer structure in which the base substrate and the lid substrate are directly bonded to each other, and the piezoelectric vibrating reed is housed in the cavity formed between the two substrates.

One example of this type of piezoelectric vibrator having the two layer structure is a piezoelectric vibrator that includes: through holes that are formed in a base substrate made of a glass material and that communicate with the cavity; through electrodes arranged inside the through holes; and external electrodes that are provided on an outer surface side of the base substrate and that are electrically connected to the piezoelectric vibrating reed via the through electrodes.

Patent Document 1: JP-A-2001-105307

As a method to form a through hole in the base substrate of the above-described piezoelectric vibrator, a method is known in which, after a recessed portion is formed on a surface side of the base substrate by a sandblasting method or press forming, for example, the recessed portion is penetrated by polishing a rear surface of the base substrate (single-side polishing). For the single-side polishing of the substrate, the following methods etc. are generally used: a method in which one of the surfaces of the substrate is attached by water suction, via a suction pad, to a holding board that holds the substrate and, in this state, the substrate is pressure-bonded to a polishing surface plate, as described in Patent Document 1, for example; and a method in which the substrate is adhered to the holding board using wax. Then, by rotatably driving the surface plate in a state in which an abrasive is interposed between the surface plate and the substrate, it is possible to polish the other surface of the substrate.

However, if the above-described single-side polishing method is adopted when forming the through hole, warpage of the base substrate is caused by the suction force of the suction pad. Due to the warpage, a polishing rate varies in a surface direction of the base substrate. Further, if the substrate is adhered using wax, there is a possibility that the substrate is held in an inclined state with respect to the holding board, due to unevenness in a wax layer thickness and the like. If polishing is performed in this state, only the same section of the substrate constantly comes in contact with a lower surface plate and is polished. As a result, variations occur in the finish thickness of the final base substrate and a degree of parallelism of the base substrate deteriorates. In other words, there is a problem of occurrence of uneven wear.

If the base substrate with uneven wear is bonded to the lid substrate, there is a possibility that a gap will be generated between their bonding surfaces. As a result, in some cases, airtightness in the cavity cannot be maintained.

The invention has been made in light of the above-described problems, and it is an object thereof to provide a glass substrate polishing method, a package manufacturing method, a piezoelectric vibrator, an oscillator, an electronic device and a radio timepiece that are capable of reducing a variation in a finish thickness in a surface direction of a glass substrate and capable of maintaining airtightness in a cavity.

### SUMMARY OF THE INVENTION

In order to achieve the above-described object, a glass substrate polishing method according to the invention is a glass substrate polishing method for polishing a glass substrate using a polishing device. The glass substrate polishing method is characterized in that the polishing device includes a surface plate that is rotationally driven around a first central axis, a plate that is rotatable around a second central axis eccentric from the first central axis and presses the glass substrate toward the surface plate, and a work holder that is formed on the plate and restricts movement of the glass substrate in a surface direction while holding the glass substrate in a state in which a central axis of the glass substrate is eccentric from the second central axis. The glass substrate is polished by rotating the surface plate while the glass substrate is rotatably held in the work holder in a state in which an abrasive is interposed between the glass substrate and the surface plate.

With this structure, it is possible to inhibit warpage of the glass substrate by polishing the glass substrate without fixing it to the plate by suction, in contrast to a case in which the glass substrate is polished in a state in which it is fixed by suction using a suction pad or the like as in related art. Further, the glass substrate is not held in an inclined state in the work holder. Furthermore, since the glass substrate is rotatably held in the work holder and at the same time, the plate on which the work holder is formed is also rotatably held, one surface of the glass substrate and the surface plate can be disposed in parallel to each other over an entire area in the surface direction. Thus, it is possible to press the glass substrate at a uniform pressing force over the entire area in the surface direction. Accordingly, since it is possible to uniformly polish the one surface of the glass substrate, it is possible to reduce variations in a finish thickness in the surface direction of the glass substrate, and it is possible to improve a degree of parallelism of the glass substrate. As a result, even when a relatively soft material, such as a glass substrate, is polished, uneven wear etc. can be inhibited and a desired finish thickness can be achieved.

Further, the method is characterized in that one surface of the glass substrate is polished such that a recessed portion formed in another surface of the glass substrate is penetrated, and a through hole is formed in the glass substrate.

With this structure, as compared with a case in which a through hole is directly formed in the glass substrate, burrs are not generated on an opening edge etc. of the through hole, and it is therefore possible to form the through hole having a good shape.

Further, the method is characterized in that a restricting member, which restricts a polishing amount of the glass substrate, is arranged on the plate in a standing condition toward the surface plate.

With this structure, since the restricting member comes in contact with the surface plate, further polishing can be restricted and control of the finish thickness of the glass substrate can be easily performed. In other words, when the control of the finish thickness is performed based on a polishing rate or the like of an abrasive as in the related art, the polishing rate changes with time due to deterioration of the abrasive, and therefore, there is a problem that film thickness control is difficult.

In contrast to this, with the structure of the invention, the finish thickness of the glass substrate can be adjusted by only determining a protruding amount of the restricting member from the plate before polishing. Therefore, the finish thickness of the glass substrate can be managed highly accurately and easily.

Further, the method is characterized in that when the finish thickness of the glass substrate is denoted by T and a maximum particle diameter of the abrasive is denoted by D, a height H of the restricting member is set to T+2D.

With this structure, by setting the height H of the restricting member to T+2D, the glass substrate can be formed to have a desired finish thickness, while taking account of: the abrasive that is interposed between the surface plate and the one surface of the glass substrate during polishing; and the particle size of the abrasive that intrudes into the work holder and is interposed between another surface of the glass substrate and a lower surface of the plate.

Further, the method is characterized in that a plurality of the work holders are formed on the plate, and a plurality of the plates are disposed along a circumferential direction of the surface plate.

With this structure, since a plurality of the glass substrates can be polished collectively, it is possible to improve work efficiency.

Further, a packaging manufacturing method of the invention is a package manufacturing method capable of enclosing an electronic component in a cavity formed between a plurality of substrates that are bonded to each other. The package manufacturing method is characterized by including: a through hole forming step of arranging through electrodes that penetrate a first substrate among the plurality of substrates in a thickness direction and conduct a current between an inside of the cavity and an outside of the package. In the through hole forming step, through holes are formed in the first substrate made of a glass material using the above-described glass substrate polishing method of the invention.

With this structure, since the above-described glass substrate polishing method of the invention is used to perform polishing, a gap is not generated between a bonding surface of the first substrate, and it is possible to bond the respective substrates in a good condition and to maintain airtightness in the cavity.

Further, a piezoelectric vibrator according to the invention is characterized by being manufactured using the above-described package manufacturing method of the invention.

With this structure, since the piezoelectric vibrator is manufactured using the above-described package manufacturing method of the invention, it is possible to provide a piezoelectric vibrator that has excellent vibration characteristics and is highly reliable.

Further, an oscillator according to the invention is characterized in that the above-described piezoelectric vibrator of the invention is electrically connected to an integrated circuit as an oscillation element.

Further, an electronic device according to the invention is characterized in that the above-described piezoelectric vibrator of the invention is electrically connected to a time measuring portion.

Further, a radio timepiece according to the invention is characterized in that the above-described piezoelectric vibrator of the invention is electrically connected to a filter portion.

Since the oscillator, the electronic device and the radio timepiece according to the invention are provided with the above-described piezoelectric vibrator, it is possible to provide products that have excellent vibration characteristics and are highly reliable.

With the glass substrate polishing method according to the invention, one surface of the glass substrate can be uniformly polished. Therefore, it is possible to reduce variations in the finish thickness in the surface direction of the glass substrate, and it is possible to improve the degree of parallelism of the glass substrate. As a result, even when a relatively soft material, such as a glass substrate, is polished, uneven wear etc. can be inhibited and a desired finish thickness can be achieved.

Further, with the package manufacturing method according to the invention, since the above-described glass substrate polishing method of the invention is used to perform polishing, a gap is not generated between a bonding surface of the first substrate, and it is possible to bond the respective substrates in a good condition and to maintain airtightness in the cavity.

Further, with the piezoelectric vibrator according to the invention, since the piezoelectric vibrator is manufactured using the above-described package manufacturing method of the invention, it is possible to provide a piezoelectric vibrator that has excellent vibration characteristics and is highly reliable.

Since the oscillator, the electronic device and the radio timepiece according to the invention are provided with the above-described piezoelectric vibrator, it is possible to provide products that have excellent vibration characteristics and are highly reliable.

### BRIEF DESCRIPTION OF THE DRAWINGS

FIG. 1 is an external perspective view showing an example of a piezoelectric vibrator according to an embodiment of the invention.

FIG. 2 is an internal structural view of the piezoelectric vibrator, and is a view showing a piezoelectric vibrating reed when viewed from above in a state in which a lid substrate is removed.

FIG. 3 is a cross-sectional view taken along a line A-A in FIG. 2.

FIG. 4 is an exploded perspective view of the piezoelectric vibrator.

FIG. 5 is a perspective view of a rivet that is used when the piezoelectric vibrator shown in FIG. 1 is manufactured.

FIG. 6 is a flowchart showing a manufacturing flow of the piezoelectric vibrator shown in FIG. 1.

FIG. 7 is a process chart illustrating a through hole forming process, and is a view showing a cross section of a base substrate wafer.

FIG. 8 is a process chart illustrating the through hole forming process, and is a view showing a cross section of the base substrate wafer.

FIG. 9 is a process chart illustrating the through hole forming process, and is a view showing a cross section of the base substrate wafer.

FIG. 10 is a schematic structural view showing a single-side polishing device that is used in a first polishing process.

FIG. 11 is a plan view of the single-side polishing device.

FIG. 12 is a plan view of a pressing plate.

FIG. 13 is a process chart illustrating the first polishing process, and is an enlarged view of the single-side polishing device.

FIG. 14 is a process chart illustrating the first polishing process, and is an enlarged view of the single-side polishing device.

FIG. 15 is a process chart illustrating the first polishing process, and is an enlarged view of the single-side polishing device.

FIG. 16 is a process chart illustrating a through electrode forming process, and is a cross-sectional view of the base substrate wafer.

FIG. 17 is a process chart illustrating the through electrode forming process, and is a cross-sectional view of the base substrate wafer.

FIG. 18 is a process chart illustrating the through electrode forming process, and is a cross-sectional view of the base substrate wafer.

FIG. 19 is a structural view showing one embodiment of an oscillator according to the invention.

FIG. 20 is a structural view showing one embodiment of an electronic device according to the invention.

FIG. 21 is a structural view showing one embodiment of a radio timepiece according to the invention.

### DETAILED DESCRIPTION OF THE PREFERRED EMBODIMENTS

Hereinafter, an embodiment of the invention will be described based on the drawings.

### (Piezoelectric Vibrator)

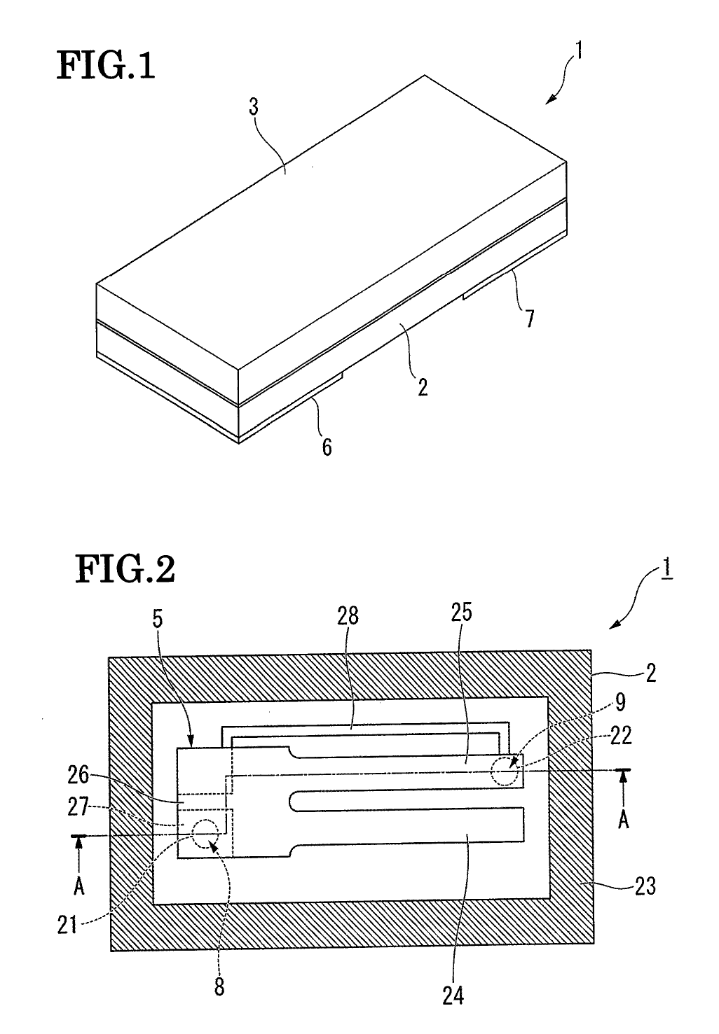

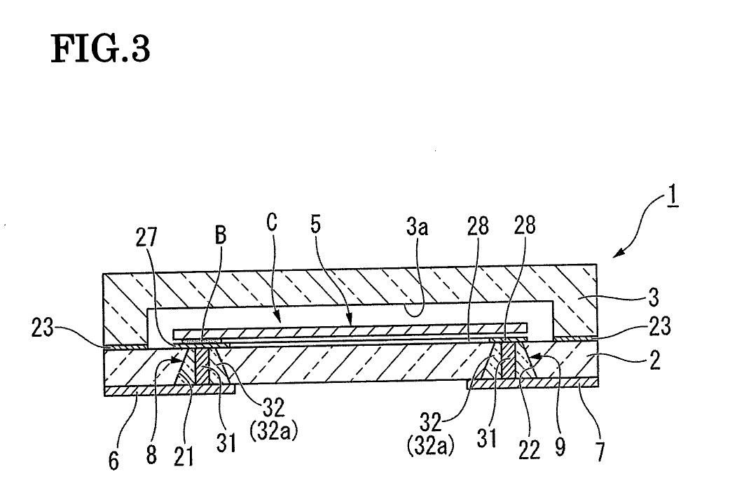

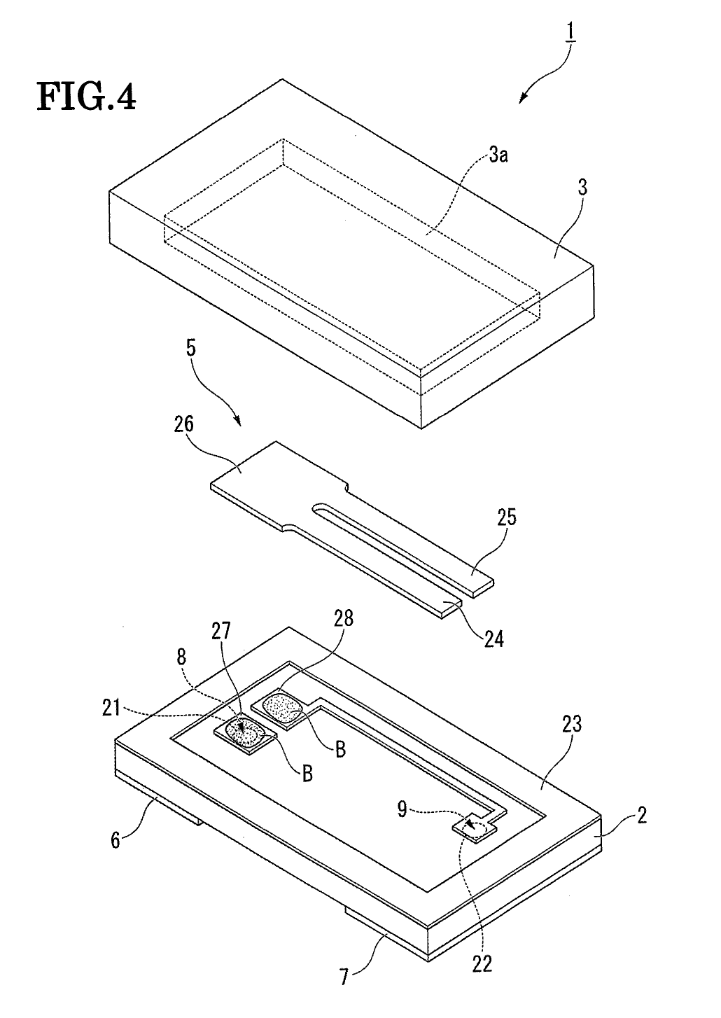

FIG. 1 is an external perspective view of a piezoelectric vibrator according to the embodiment. FIG. 2 is an internal structural view of the piezoelectric vibrator, and is a view showing a piezoelectric vibrating reed when viewed from above in a state in which a lid substrate is removed. Further, FIG. 3 is a cross-sectional view of the piezoelectric vibrator taken along a line A-A shown in FIG. 2, and FIG. 4 is an exploded perspective view of the piezoelectric vibrator.

As shown in FIG. 1 to FIG. 4, a piezoelectric vibrator 1 is formed in a box shape such that a base substrate 2 and a lid substrate 3 are laminated in two layers, and is the surface mount type piezoelectric vibrator 1 in which a piezoelectric vibrating reed 5 is housed in an internal cavity C. The piezoelectric vibrating reed 5 and external electrodes 6, 7 that are arranged on an outside of the base substrate 2 are electrically connected by a pair of through electrodes 8, 9 that penetrate the base substrate 2.

The base substrate 2 is a transparent insulating substrate made of a glass material, such as soda lime glass for example, and is formed in a plate shape. A pair of through holes 21, 22, in which the pair of through electrodes 8, 9 are formed, are formed in the base substrate 2. The through holes 21, 22 have a tapered cross section and the diameter is gradually reduced from a lower surface toward an upper surface of the base substrate 2.

Similarly to the base substrate 2, the lid substrate 3 is a transparent insulating substrate made of a glass material, such as soda lime glass for example, and is formed in a plate shape having a size that can be overlapped and aligned with the base substrate 2. A rectangular-shaped recessed portion 3a, in which the piezoelectric vibrating reed 5 is housed, is formed on a bonding surface side of the lid substrate 3 to which the base substrate 2 is bonded.

When the base substrate 2 and the lid substrate 3 are overlapped with each other, the recessed portion 3a forms the cavity C that houses the piezoelectric vibrating reed 5. The lid substrate 3 is anodically bonded to the base substrate 2 via a bonding layer 23 in a state in which the recessed portion 3a faces the base substrate 2 side.

The piezoelectric vibrating reed 5 is a tuning-fork type vibrating reed formed of a piezoelectric material, such as crystal, lithium tantalate, lithium niobate or the like, and it vibrates when a predetermined voltage is applied.

The piezoelectric vibrating reed 5 has a general U-shape in a plan view, and is formed by a pair of vibrating arm portions 24, 25 that are disposed parallel to each other, and a base portion 26 that integrally fixes a base end side of the pair of vibrating arm portions 24, 25. Provided on outer surfaces of the pair of vibrating arm portions 24, 25 are: a pair of excitation electrodes formed by a first excitation electrode and a second excitation electrode (which are not shown in the drawings) that vibrate the vibrating arm portions 24, 25; and a pair of mount electrodes (both of which are not shown in the drawings) that are electrically connected to the first excitation electrode and the second excitation electrode.

As shown in FIG. 3 and FIG. 4, the piezoelectric vibrating reed 5 structured in this manner is bump bonded onto routing electrodes 27, 28 formed on the upper surface of the base substrate 2, using a bump B such as gold. More specifically, the first excitation electrode of the piezoelectric vibrating reed 5 is bump bonded onto one of the routing electrodes, the routing electrode 27, via one of the mount electrodes and the bump B, and the second excitation electrode is bump bonded onto the other of the routing electrodes, the routing electrode 28, via the other of the mount electrodes and the bump B. Thus, the piezoelectric vibrating reed 5 is supported in a floating state with respect to the upper surface of the base substrate 2. At the same time, each of the mount electrodes and the routing electrodes 27, 28 are respectively electrically connected.

Further, the external electrodes 6, 7 are provided on both ends, in a longitudinal direction, of the lower surface of the base substrate 2, and are electrically connected to the piezoelectric vibrating reed 5 via each of the through electrodes 8, 9 and each of the routing electrodes 27, 28. More specifically, one of the external electrodes, the external electrode 6, is electrically connected to one of the mount electrodes of the piezoelectric vibrating reed 5 via one of the through electrodes, the through electrode 8, and one of the routing electrodes, the routing electrode 27. Meanwhile, the other of the external electrodes, the external electrode 7, is electrically connected to the other of the mount electrodes of the piezoelectric vibrating reed 5 via the other of the through electrodes, the through electrode 9, and the other of the routing electrodes, the routing electrode 28.

The through electrodes 8, 9 are formed by core portions 31 that are respectively disposed on central axes of the through holes 21, 22, and cases 32 that are formed by firing a glass frit 32a that is filled between the core portions 31 and the through holes 21, 22. One of the through electrodes, the through electrode 8, is located below the routing electrode 27 and between the external electrode 6 and the base portion 26. The other of the through electrodes, the through electrode 9, is located above the external electrode 7 and below the routing electrode 28.

In the through electrodes 8, 9, the cases 32 integrally fix the core portions 31 with respect to the through holes 21, 22, and the core portions 31 and the cases 32 completely seal the through holes 21, 22 to maintain airtightness in the cavity C.

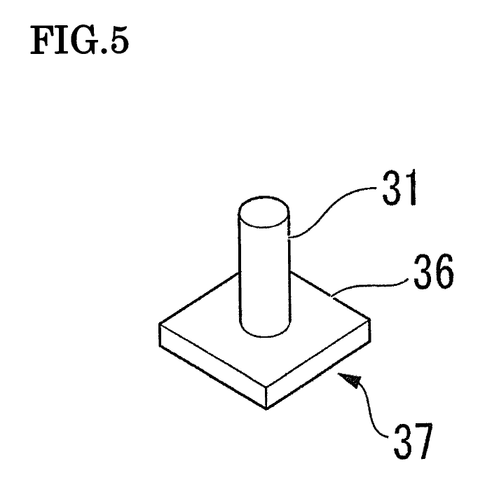

FIG. 5 is a perspective view of a rivet. Each core portion 31 is a conductive metal core which is formed in a column shape such that both ends thereof are flat, and which has the same thickness as that of the base substrate 2. Further, each core portion 31 is formed such that, when the through electrodes 8, 9 are formed as final products, it has a column shape and the same thickness as that of the base substrate 2 as described above. However, in a manufacturing process, as shown in FIG. 5, the core portion 31 forms a rivet 37 together with a flat plate-shaped base portion 36 that is connected to one of the ends of the core portion 31. Further, in a manufacturing process, the base portion 36 is polished and removed (which will be described later in a manufacturing method).

In other words, the electrical conductivity of the through electrodes 8, 9 is maintained through each of the conductive core portions 31.

The cases 32 are formed by firing the glass frit 32a in a paste form, and both ends thereof are flat and a thickness thereof is substantially the same as that of the base substrate 2. A through hole, through which the core portion 31 passes, is formed along the central axis. The cases 32 have a tapered outer shape that is the same shape as the through holes 21, 22. The cases 32 are fired in a state in which they are respectively embedded in the through holes 21, 22, and they are firmly fixed to the through holes 21, 22 while firmly fixing the core portions 31.

When the piezoelectric vibrator 1 structured in this manner is operated, a predetermined driving voltage is applied to the external electrodes 6, 7 that are formed in the base substrate 2. Thus, it is possible to apply a current to each of the excitation electrodes of the piezoelectric vibrating reed 5, and it is possible to cause the pair of vibrating arm portions 24, 25 to vibrate at a predetermined frequency in approaching and separating directions. Then, by using the vibration of the pair of vibrating arm portions 24, 25, use is possible as a time source, a timing source of control signals and a reference signal source etc.

### (Piezoelectric Vibrator Manufacturing Method)

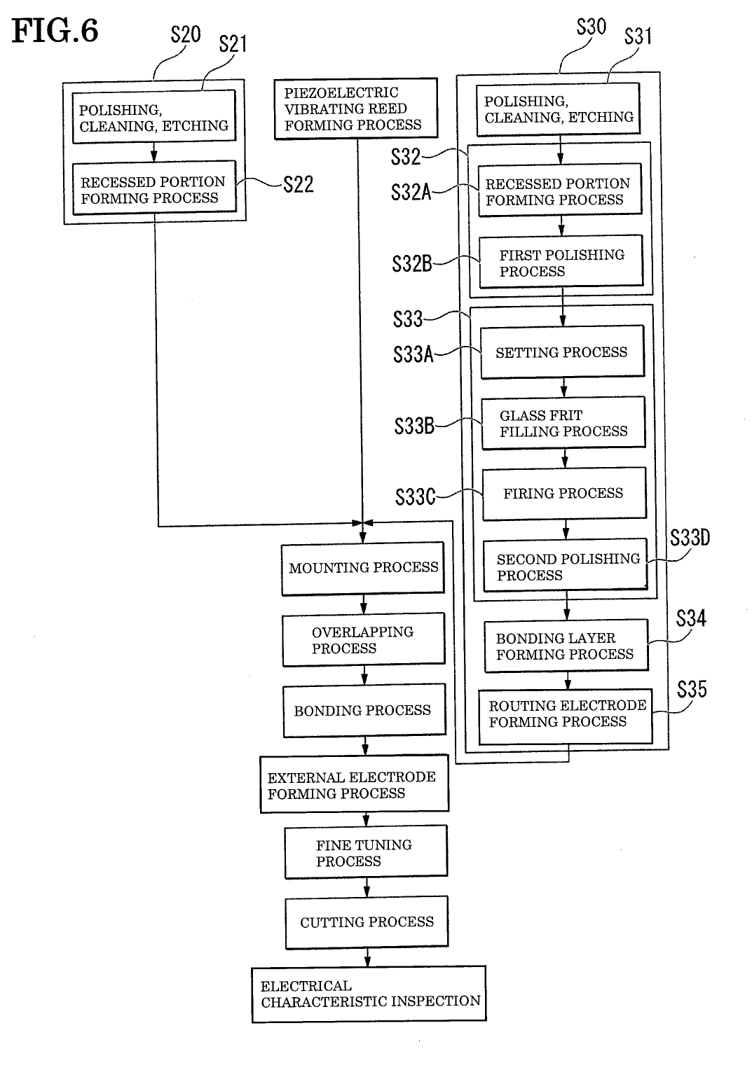

Next, a manufacturing method of the above-described piezoelectric vibrator will be described with reference to the flowchart shown in FIG. 6.

First, a first wafer forming process is performed in which a lid substrate wafer (not shown in the drawings), which later becomes the lid substrate 3, is formed up to a state immediately before performing anodic bonding (S20). More specifically, after the soda lime glass is polished and processed to a predetermined thickness and then cleaned, the disc-shaped lid substrate wafer, from which a work-affected layer on an outermost surface has been removed by etching or the like, is formed (S21). Then, a recessed portion forming process is performed, in which a plurality of the recessed portions 3a for cavities are formed in a row direction by etching or the like in a bonding surface of the lid substrate wafer (S22). At this point in time, the first wafer forming process ends.

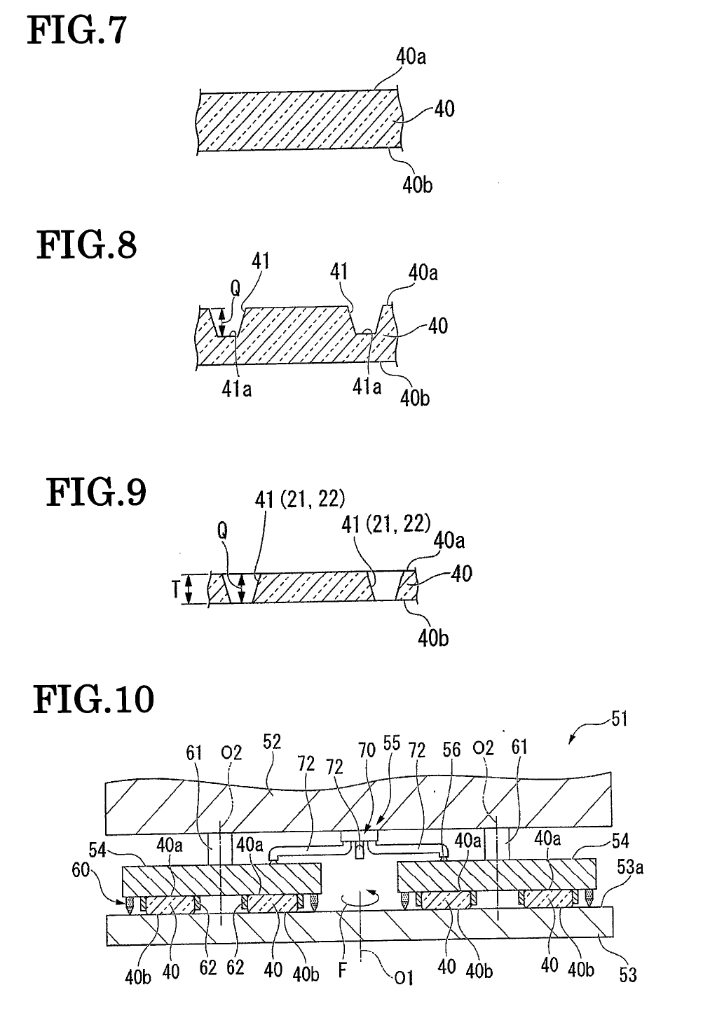

Next, concurrently with the above-described process, or at a timing before or after it, a second wafer forming process is performed in which a base substrate wafer 40 (refer to FIG. 7), which later becomes the base substrate 2, is formed up to a state immediately before performing anodic bonding (S30). First, after the soda lime glass is polished and processed to a predetermined thickness and then cleaned, the disc-shaped base substrate wafer 40, from which a work-affected layer on an outermost surface has been removed by etching or the like, is formed (S31). Next, a through hole forming process is performed in which a plurality of the through holes 21, 22 for disposing the pair of through electrodes 8, 9 are formed in the base substrate wafer 40 (S32).

Here, the above-described through hole forming process (S32) will be described in detail. FIG. 7 to FIG. 9 are process charts for the through hole forming process and show cross sections of the base substrate wafer.

First, as shown in FIG. 7, the base substrate wafer 40 formed in the second wafer forming process (S30) is prepared, and as shown in FIG. 8, recessed portions 41 with a predetermined depth Q, which later become the through holes 21, 22 (refer to FIG. 2), are formed in a surface 40a of the base substrate wafer 40 (S32A: a recessed portion forming process). Specifically, by performing press working on the base substrate wafer 40, the recessed portions 41 are formed to have a tapered cross section such that an inner diameter thereof is gradually increased from a bottom surface 41 a toward an opening edge. Note that, in the embodiment, the surface (the other surface) 40a of the base substrate wafer 40 is a surface that becomes the lower surface of the above-described base substrate 2 (refer to FIG. 3), and a rear surface (one surface) 40b is a surface that becomes the upper surface of the base substrate 2.

### (First Polishing Process)

Next, the rear surface 40b of the base substrate wafer 40 is polished and thus the recessed portions 41 are caused to penetrate in a thickness direction of the base substrate wafer 40 (S32B: a first polishing process).

Polishing of the base substrate wafer 40 is performed using a single-side polishing device 51 such as that shown in FIG. 10.

### (Single-Side Polishing Device)

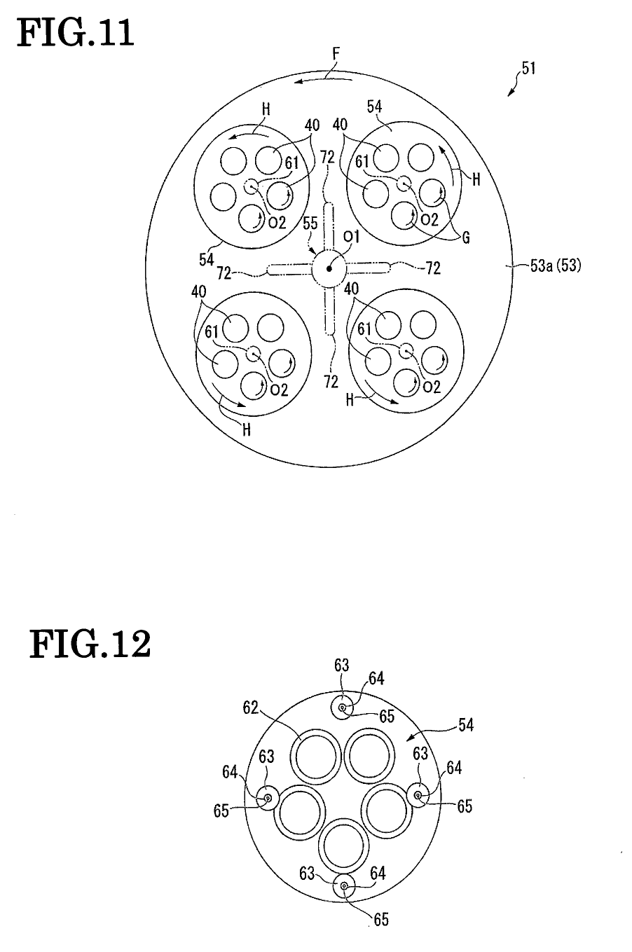

FIG. 10 is a schematic structural view of the single-side polishing device, and FIG. 11 is a plan view of the single-side polishing device.

As shown in FIG. 10 and FIG. 11, the single-side polishing device 51 mainly includes: an upper surface plate 52 having a round shape in a plan view; a lower surface plate (surface plate) 53 that is formed in the same shape as the upper surface plate 52; pressing plates (plates) 54 that are connected to the upper surface plate 52 and press the base substrate wafer 40 toward the lower surface plate 53; abrasive inlet means 55 for inletting an abrasive 56 between the upper surface plate 52 and the lower surface plate 53; and driving means (not shown in the drawings) for driving the lower surface plate 53 to rotate around a central axis O1.

The lower surface plate 53 is made of special alloy steel so that it is not polished by contact with diamond points 60, which will be described later, and grooves (not shown in the drawings) are formed in an upper surface (a polishing surface) 53a of the lower surface plate 53, by cutting in a radial pattern from the central axis (the first central axis) O1 toward a radially outer side. The lower surface plate 53 is rotatably supported around the central axis O1 by driving the above-described driving means.

The pressing plates 54 are disc-shaped pressing plates made of ceramic or the like, and a plurality of the pressing plates 54 (the number of which is four, for example) are disposed at equal intervals along a circumferential direction of the lower surface plate 53. More specifically, a central axis (a second central axis) O2 of each of the pressing plates 54 is disposed at a position that is eccentric with respect to the central axis O1 of the lower surface plate 53. A plate shaft 61, which is arranged in a standing condition along the central axis O2 of each of the pressing plates 54, is fixed to the upper surface of each of the pressing plates 54. An upper end side of the plate shaft 61 is rotatably supported by the upper surface plate 52, and each of the pressing plates 54 is structured to rotate around the central axis 02 in conjunction with rotation of the lower surface plate 53.

FIG. 12 is a plan view of the pressing plate.

As shown in FIG. 12, a lower surface (a surface facing the lower surface plate 53) of the pressing plate 54 is provided with a plurality of work holders 62 (the number of which is five, for example) at equal intervals along a circumferential direction thereof. Each of the work holders 62 is a ring-shaped member having an inner diameter that is slightly larger than the diameter of the base substrate wafer 40, and is arranged in a standing condition from the lower surface toward the lower surface plate 53 (refer to FIG. 10). In other words, each of the work holders 62 houses the base substrate wafer 40 in a state in which a central axis of the base substrate wafer 40 is eccentric with respect to the central axis 02 of the pressing plate 54, and thus movement of the base substrate wafer 40 toward the surface direction is restricted during polishing. Since the plurality of work holders 62 are formed on the pressing plate 54 in this manner, it is possible to polish a plurality of the base substrate wafers 40 collectively. Therefore, it is possible to improve work efficiency.

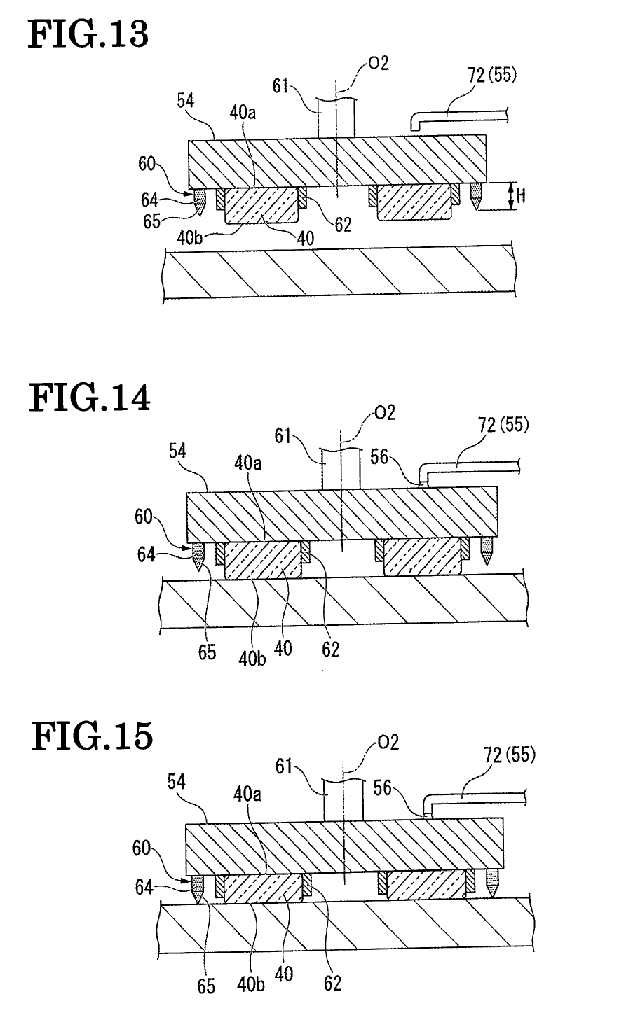

Further, on an outer circumferential side of the lower surface of the pressing plate 54, a plurality of the diamond points (restricting members) 60 (the number of which is four, for example) are provided at equal intervals along the circumferential direction. Each of the diamond points 60 has a ball screw structure and includes: a base portion 63 that is provided on the pressing plate 54 and has a screw hole that penetrates in a thickness direction of the pressing plate 54; a screw shaft 64 screwed into the screw hole; and a diamond portion 65 that is attached to a tip end (a lower end) of the screw shaft 64 and that is formed to be tapered toward a tip end thereof. The diamond point 60 is a component to control a finish thickness T of the base substrate wafer 40, and the tip end of the diamond portion 65 comes in contact with the lower surface plate 53 during polishing and further polishing is thereby restricted. More specifically, the diamond point 60 is designed such that it can adjust a protruding amount (height) H (refer to FIG. 13), of the screw shaft 64 and the diamond portion 65, from the lower surface of the pressing plate 54. Thus, it is possible to set the finish thickness T of the base substrate wafer 40. Note that the finish thickness T of the base substrate wafer 40 in the first polishing process (S32B) of the embodiment has the same value as the depth Q of the location where the bottom surface 41a of the recessed portion 41 penetrates, namely, of the recessed portion 41.

The abrasive inlet means 55 includes a reservoir portion (not shown in the drawings) in which the abrasive 56 is stored, and a supply portion 70 that is connected to the reservoir portion via a pump and supplies the abrasive 56 supplied from the reservoir portion to the upper surface 53a of the lower surface plate 53. The supply portion 70 is disposed coaxially with the central axis O1 of the lower surface plate 53, and includes a plurality of supply pipes 72 radially extending from the supply portion 70. The supply pipes 72 extend outwardly in a radial direction of the lower surface plate 53 between the respective pressing plates 54, and supply ports at their tip ends are disposed on the inner side of the plate shaft 61 in the radial direction of the lower surface plate 53.

FIG. 13 to FIG. 15 are process charts of the first polishing process, and are enlarged views of the above-described single-side polishing device. In order to perform the first polishing process (S32B) using the above-described single-side polishing device 51, first as shown in FIG. 13, the base substrate wafer 40 is set in each of the work holders 62 of the pressing plate 54. Specifically, the base substrate wafer 40 is adhered using water to the lower surface of the pressing plate 54 in a state in which the surface 40a of the base substrate wafer 40 faces the lower surface of the pressing plate 54. Note that, since the base substrate wafer 40 is simply adhered using water to the lower surface of the pressing plate 54, the base substrate wafer 40 falls off from the pressing plate 54 after elapse of a predetermined period of time or immediately after the start of polishing. In other words, in the embodiment, it is sufficient that the base substrate wafer 40 is held to the pressing plate 54 by suction until the base substrate wafer 40 is transferred to a polishing start position.

Next, based on the finish thickness T of the base substrate wafer 40, the protruding amount H of the diamond point 60 (the screw shaft 64 and the diamond portion 65) is adjusted. In this case, supposing that, at a point in time at which the recessed portion 41 of the base substrate wafer 40 penetrates, the thickness of the base substrate wafer 40 is the finish thickness T and the maximum particle diameter of the abrasive 56 supplied from the abrasive inlet means 55 is D, the protruding amount H of the diamond point 60 is preferably set to approximately T+2D. This is in order to take account of the abrasive 56 that is interposed between the lower surface plate 53 and the rear surface 40b of the base substrate wafer 40 during polishing; and the particle size of the abrasive 56 that intrudes into the work holder 62 and is interposed between the surface 40a of the base substrate wafer 40 and the lower surface of the pressing plate 54. Note that, in the first polishing process (S32B) of the embodiment, although there are cases in which the abrasive 56 is interposed between the surface 40a of the base substrate wafer 40 and the lower surface of the pressing plate 54 as described above, the surface 40a of the base substrate wafer 40 is rarely polished and there is no possibility of a failure occurring after the polishing.

Next, the abrasive inlet means 55 is driven and the abrasive 56 is supplied onto the lower surface plate 53 from the supply ports. Then, as shown in FIG. 14, the pressing plate 54 is lowered and the rear surfaces 40b of the base substrate wafers 40 are pressed toward the lower surface plate 53 at a predetermined pressing force.

After that, the driving means of the lower surface plate 53 is driven and the lower surface plate 53 is rotated around the central axis O1. Thus, the polishing of the base substrate wafers 40 is started.

Here, as shown in FIG. 11 and FIG. 14, when the lower surface plate 53 rotates around the central axis O1 (refer to an arrow F in FIG. 11), first, the suction between the base substrate wafers 40 and the pressing plate 54 is released due to a frictional force between the lower surface plate 53 and the base substrate wafers 40. By this, the base substrate wafers 40 are movably held in the work holders 62 in a state in which the movement only in the surface direction is restricted by the work holders 62. As a result, due to the frictional force between the lower surface plate 53 and the base substrate wafers 40, the base substrate wafers 40 start to rotate in the work holders 62 (in a direction of arrows G in FIG. 11, for example).

Further, due to the frictional force between the pressing plate 54 and the base substrate wafers 40, the pressing plate 54 starts to rotate around the central axis O2 (refer to arrows H in FIG. 11). In this manner, in the first polishing process (S32B) of the embodiment, in conjunction with the rotation of the lower surface plate 53, the pressing plate 54 rotates around the central axis O2 and the base substrate wafers 40 rotate around the central axis thereof. By this, the lower surface plate 53 and the base substrate wafers 40 relatively move in a state in which the abrasive 56 is interposed therebetween, and it is therefore possible to continuously polish the rear surfaces 40b of the base substrate wafers 40. In this case, the base substrate wafers 40 are polished while they are freely rotating inside the work holders 62. Therefore, in-plane variations of the finish thickness T can be inhibited, and the base substrate wafers 40 with a high degree of parallelism can be formed.

As shown in FIG. 15, if the rear surfaces 40b of the base substrate wafers 40 are continued to be polished, the diamond portions 65 of the diamond points 60 come into contact with the lower surface plate 53. At this time, since the diamond portions 65 are designed not to be polished by the lower surface plate 53, the pressing plate 54 does not move downward any more. Thus, the pressing force applied from the pressing plate 54 to the base substrate wafers 40 is released, and it is possible to suppress further polishing of the base substrate wafers 40 beyond the finish thickness T. A determination as to whether or not the diamond portions 65 come into contact with the lower surface plate 53 can be made by a contact sound etc. of the diamond portions 65 with the above-described grooves formed on the lower surface plate 53.

Then, as shown in FIG. 9, by the base substrate wafer 40 being polished to have the finish thickness T, the bottom surfaces 41 a of the recessed portions 41, which are formed to have the predetermined depth Q in the surface 40a of the base substrate wafer 40, penetrate to the rear surface 40b of the base substrate wafer 40. Thus, the through holes 21, 22 that penetrate in the thickness direction can be formed in the base substrate wafer 40. In this manner, in the embodiment, the through holes 21, 22 can be formed by penetrating the recessed portions 41 after the recessed portions 41 have been formed by press working. Therefore, through holes are not formed directly in the base substrate wafer 40. For that reason, burrs are not generated on opening edges etc. of the through holes 21, 22, and it is therefore possible to form the through holes 21, 22 having a good shape.

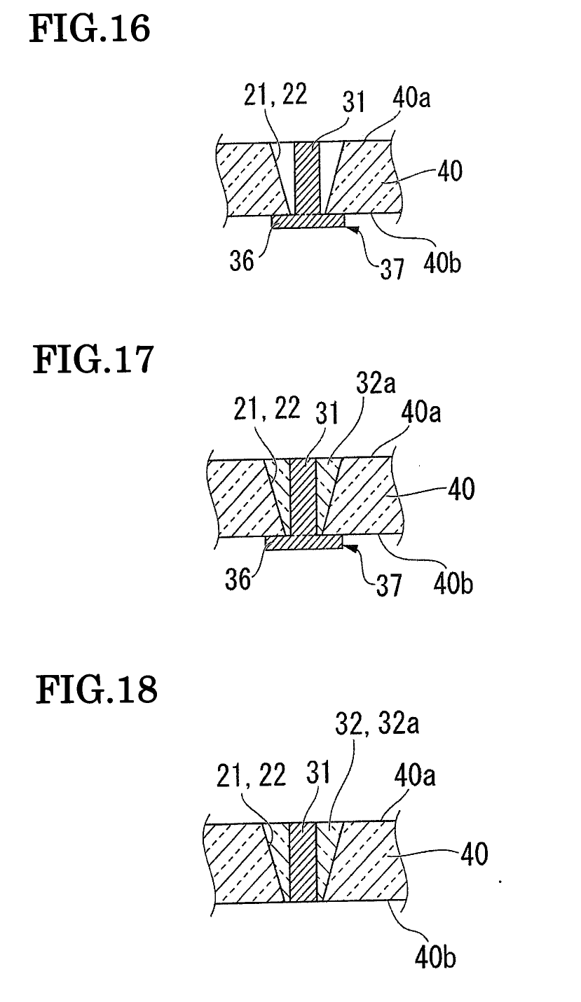

FIG. 16 to FIG. 18 are process charts illustrating a through electrode forming process, and show cross-sectional views of the base substrate wafer 40.

Next, as shown in FIG. 6 and FIG. 16, the through electrode forming process (S33) is performed in which the through electrodes 8, 9 are formed in the through holes 21, 22 that have been formed in the first polishing process (S32B).

Specifically, the core portion 31 of the rivet 37 is inserted into each of the through holes 21, 22 from the rear surface 40b side of the base substrate wafer 40 (S33A). After that, as shown in FIG. 17, a gap between each of the through holes 21, 22 and the core portion 31 is filled with the glass frit 32a in a paste form (S33B), and the glass frit 32a is fired at a predetermined temperature to be solidified (S33C).

In this manner, by causing the base portion 36 to be in contact with the rear surface 40b of the base substrate wafer 40, the glass frit 32a in a paste form can be reliably filled in the through holes 21, 22. Further, since the base portion 36 is formed in a flat plate shape, the rivet 37 and the base substrate wafer 40 provided with the rivet 37 are stable without looseness. Thus, it is possible to improve work efficiency. In particular, the rear surface 40b of the base substrate wafer 40 is formed, in the above-described first polishing process, as a surface with minimum variations in the finish thickness T and with a high degree of parallelism. Therefore, it is possible to reliably inhibit looseness of the rivet 37.

The glass frit 32a is fired and solidified and fixes the rivet 37 in a close contact state. At the same time, it can seal the through holes 21, 22 by firmly adhering to the through holes 21, 22.

Next, as shown in FIG. 18, the base portion 36 of the rivet 37 is polished and removed (S33D: a second polishing process). By this, the core portion 31 can be maintained in each of the through holes 21, 22 such that it is flush with the surface 40a of the base substrate wafer 40. With the above-described processes, it is possible to form the through electrodes 8, 9.

Next, a bonding layer forming process is performed in which a conductive material is patterned onto the upper surface of the base substrate wafer 40 and the bonding layer 23 is thereby formed (S34). At the same time, a routing electrode forming process is performed (S35). In this way, the manufacturing process of the base substrate wafer 40 ends.

Then, the piezoelectric vibrating reed 5 is disposed in the cavity C, which is formed by the base substrate wafer 40 formed in this way and the lid substrate wafer, and is thereby mounted on the through electrodes 8, 9. The base substrate wafer 40 and the lid substrate wafer are anodically bonded together to form a wafer bonded body.

Then, the pair of external electrodes 6, 7 that are electrically connected to the pair of through electrodes 8, 9, respectively, are formed and the frequency of the piezoelectric vibrator 1 is fine tuned. Then, the wafer bonded body is cut into small pieces and an inspection of internal electrical characteristics is performed, thereby forming a package (the piezoelectric vibrator 1) that houses the piezoelectric vibrating reed.

In this manner, in the embodiment, in conjunction with the rotation of the lower surface plate 53, each pressing plate 54 is rotated around the central axis 02 and at the same time, the base substrate wafers 40 are rotated in the work holders 62.

With this structure, in the first polishing process, the base substrate wafers 40 rotate in the work holders 62 due to the frictional force between the lower surface plate 53 and the base substrate wafers 40, and at the same time, the pressing plate 54 rotates around the central axis O2 due to the frictional force between the base substrate wafers 40 and the pressing plate 54. In other words, it is possible to inhibit warpage of the base substrate wafer 40 by polishing the base substrate wafer 40 without fixing the base substrate wafer 40 to the pressing plate 54 by suction, in contrast to a case in which the base substrate wafer 40 is polished in a state in which it is fixed to the pressing plate 54 by suction using a suction pad or the like as in the related art. Further, the base substrate wafer 40 is not held in an inclined state in the work holder 62.

Thus, the rear surface 40b of the base substrate wafer 40 and the upper surface 53a of the lower surface plate 53 can be disposed parallel to each other over the entire area in the surface direction. Therefore, the base substrate wafer 40 can be pressed with a uniform pressing force over the entire area in the surface direction. Accordingly, since it is possible to uniformly polish the rear surface 40b of the base substrate wafer 40, it is possible to reduce a variation in the finish thickness T in the surface direction of the base substrate wafer 40, and it is possible to improve the degree of parallelism of the base substrate wafer 40. As a result, even when a relatively soft material, such as a glass substrate, is polished, uneven wear etc. can be inhibited.

Further, the control of the finish thickness T of the base substrate wafer 40 can be easily managed by performing the control of the finish thickness T of the base substrate wafer 40 using the diamond point 60, in contrast to a case in which the control of the finish thickness T is performed based on the polishing rate or the like of the abrasive 56 as in the related art. More specifically, since the polishing rate of the abrasive 56 changes with time due to deterioration of the abrasive 56, there is a problem that the control of the finish thickness T is difficult. In contrast to this, when the diamond point 60 is used, it is possible to adjust the finish thickness T by only determining the protruding amount H of the screw shaft 64 and the diamond portion 65 before polishing. Further, it is possible to restrict further polishing because the diamond portion 65 comes in contact with the lower surface plate 53. Therefore, the control of the finish thickness T of the base substrate wafer 40 can be managed highly accurately and easily.

In addition, by setting the protruding amount H of the diamond point 60 to T+2D, the base substrate wafer 40 can be formed to have a desired finish thickness, while taking account of: the abrasive 56 that is interposed between the lower surface plate 53 and the rear surface 40b of the base substrate wafer 40 during polishing; and the particle size of the abrasive 56 that intrudes into the work holder 62 and is interposed between the surface 40a of the base substrate wafer 40 and the lower surface of the pressing plate 54.

Then, the base substrate wafer 40 formed in this manner is bonded to the lid substrate wafer. Therefore, the two wafers can be bonded together in a good condition without generating a gap between the bonding surfaces of the two wafers, and it is possible to maintain airtightness in the cavity C. As a result, it is possible to provide the piezoelectric vibrator 1 that has excellent vibration characteristics and is highly reliable.

### (Oscillator)

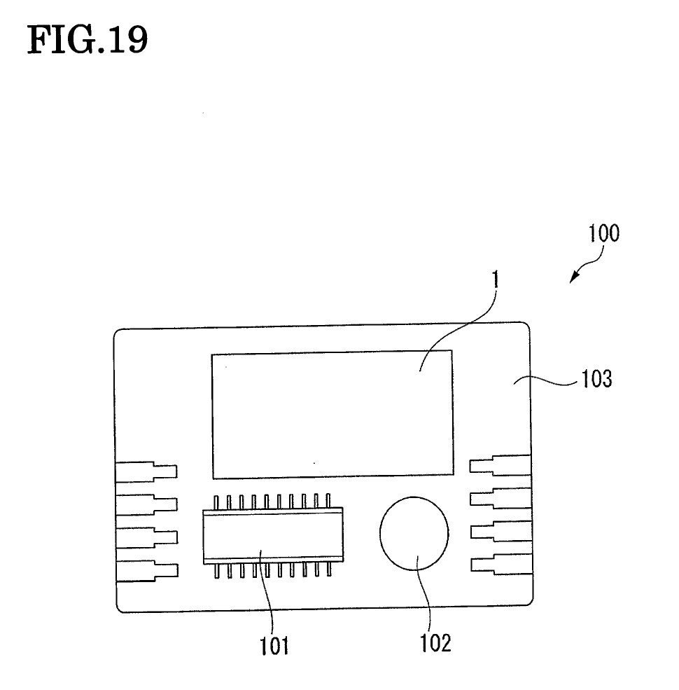

Next, one embodiment of an oscillator according to the invention will be described with reference to FIG. 19.

In an oscillator 100 of the embodiment, the piezoelectric vibrator 1 is formed as an oscillation element that is electrically connected to an integrated circuit 101 as shown in FIG. 19. The oscillator 100 is provided with a substrate 103 on which an electronic component 102 such as a capacitor is mounted. The above-described integrated circuit 101 for the oscillator is mounted on the substrate 103, and the piezoelectric vibrator 1 is mounted in the vicinity of the integrated circuit 101. The electronic component 102, the integrated circuit 101 and the piezoelectric vibrator 1 are respectively and electrically connected by wiring patterns, which are not shown in the drawings. Note that each of the structural components is molded by resin, which is not shown in the drawings.

In the oscillator 100 structured in this manner, when a voltage is applied to the piezoelectric vibrator 1, the piezoelectric vibrating reed 5 in the piezoelectric vibrator 1 vibrates. The vibration is converted to an electrical signal by a piezoelectric property of the piezoelectric vibrating reed 5, and input to the integrated circuit 101 as an electrical signal. The input electrical signal is subjected to various types of processing by the integrated circuit 101 and is output as a frequency signal. Thus, the piezoelectric vibrator 1 functions as an oscillation element.

Further, by selectively setting the structure of the integrated circuit 101, for example, to an RTC (real time clock) module or the like in response to demand, in addition to a single-function oscillator for a timepiece and the like, it is possible to add a function of controlling an operation date or time of the device or an external device or a function of providing time or a calendar.

As described above, since the oscillator 100 of the embodiment is provided with the piezoelectric vibrator 1 with improved quality, similarly, the oscillator 100 itself can also be improved in quality. In addition to this, stable and highly accurate frequency signals can be obtained over a long period of time.

### (Electronic Device)

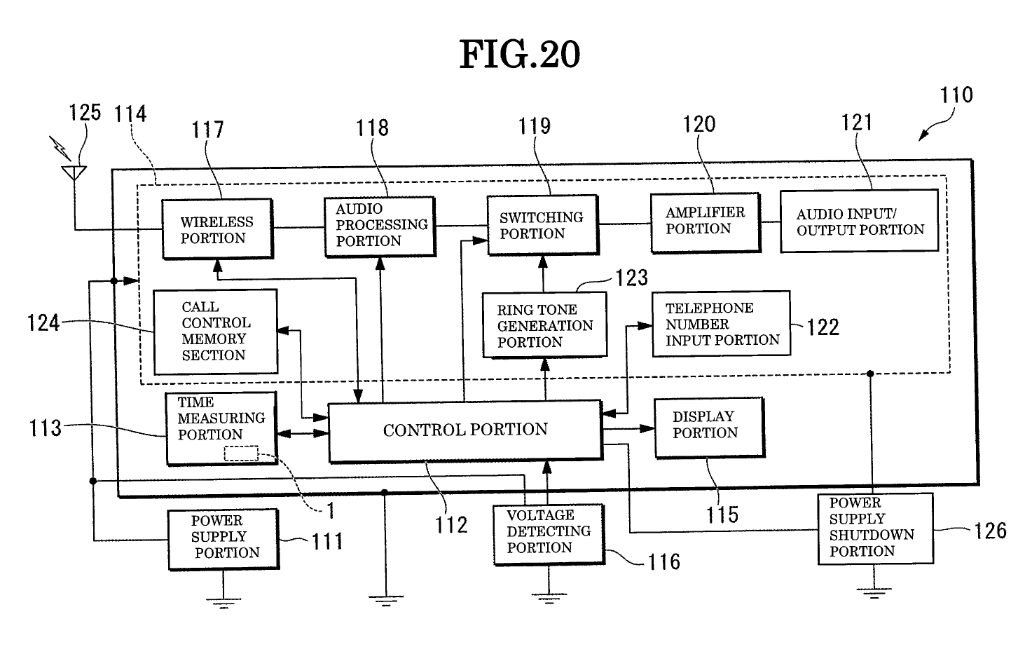

Next, one embodiment of an electronic device according to the invention will be described with reference to FIG. 20. Note that a portable information device 110 having the above-described piezoelectric vibrator 1 will be described as an example of the electronic device. First, the portable information device 110 according to the embodiment is represented by a mobile phone, for example, and is made by developing and improving a wrist watch in the related art. The external appearance is similar to the wrist watch, and a liquid crystal display is arranged in a section corresponding to a dial plate so that current time and the like can be displayed on its screen. When being used as a communication device, it can be removed from the wrist, and communication similar to a mobile phone of related art can be performed using a speaker and a microphone incorporated in an inner side section of a band. However, as compared to the mobile phone of the related art, it is dramatically compact and lightweight.

Next, the structure of the portable information device 110 of the embodiment will be described. As shown in FIG. 20, the portable information device 110 is provided with the piezoelectric vibrator 1 and a power supply portion 111 to supply electric power. The power supply portion 111 is formed by a lithium secondary battery, for example. A control portion 112 that performs various types of control, a time measuring portion 113 that counts time etc., a communication portion 114 that performs communication with the outside, a display portion 115 that displays various types of information, and a voltage detection portion 116 that detects a voltage of each of the functional portions are connected in parallel to the power supply portion 111. Electric power is supplied to each of the functional portions by the power supply portion 111.

The control portion 112 controls each of the functional portions and thereby performs operation control of the entire system, such as transmission and reception of audio data, measurement and display of current time, and the like. Further, the control portion 112 is provided with a ROM into which a program is written in advance, a CPU that reads and executes the program written into the ROM, a RAM that is used as a work area of the CPU, and the like.

The time measuring portion 113 is provided with an integrated circuit that incorporates an oscillation circuit, a register circuit, a counter circuit and an interface circuit etc., and the piezoelectric vibrator 1. When a voltage is applied to the piezoelectric vibrator 1, the piezoelectric vibrating reed 5 vibrates. The vibration is converted to an electrical signal due to piezoelectric property of crystal, and is input to the oscillation circuit as the electrical signal. The output of the oscillation circuit is binarized and measured by the register circuit and the counter circuit. Then, signal transmission and reception with the control portion 112 is performed via the interface circuit, and current time, current date or calendar information etc. is displayed on the display portion 115.

The communication portion 114 has similar functions to those of the mobile phone of the related art, and is provided with a wireless portion 117, an audio processing portion 118, a switching portion 119, an amplifier portion 120, an audio input/output portion 121, a telephone number input portion 122, a ring tone generation portion 123 and a call control memory portion 124.

The wireless portion 117 carries out transmission and reception of various types of data, such as audio data, with a base station via an antenna 125. The audio processing portion 118 encodes and decodes an audio signal input from the wireless portion 117 or the amplifier portion 120. The amplifier portion 120 amplifies a signal input from the audio processing portion 118 or the audio input/output portion 121 to a predetermined level. The audio input/output portion 121 is formed by a speaker, a microphone and the like, and makes a ring tone and incoming audio louder and collects audio.

The ring tone generation portion 123 generates a ring tone in response to a call from the base station. The switching portion 119 switches the amplifier portion 120 connected to the audio processing portion 118 to the ring tone generation portion 123 only when a call arrives, so that the ring tone generated in the ring tone generation portion 123 is output to the audio input/output portion 121 via the amplifier portion 120.

Note that the call control memory portion 124 stores a program relating to incoming and outgoing call control for communications. The telephone number input portion 122 includes, for example, numeric keys from 0 to 9 and other keys and the telephone number of a call destination is input by depressing these numeric keys and the like.

The voltage detection portion 116 detects a voltage drop and notifies the control portion 112 of it when a voltage applied by the power supply portion 111 to each of the functional portions, such as the control portion 112, drops below a predetermined value. The predetermined voltage value in this case is a value pre-set as the lowest voltage necessary to operate the communication portion 114 stably, and is, for example, about 3V. When receiving a notification of the voltage drop from the voltage detection portion 116, the control portion 112 disables operations of the wireless portion 117, the audio processing portion 118, the switching portion 119 and the ring tone generation portion 123. In particular, it is essential to stop the operation of the wireless portion 117 that consumes a large amount of electric power. Furthermore, a message informing that the communication portion 114 is unavailable due to insufficient battery power is displayed on the display portion 115.

More specifically, it is possible to disable the operation of the communication portion 114 by the voltage detection portion 116 and the control portion 112, and to display the notification message on the display portion 115. Although a character message may be used for this display, an x (cross) mark may be put on a telephone icon displayed on an upper section of a display screen of the display portion 115, as a more intuitive display.

Note that, by providing a power supply shutdown portion 126 that is capable of selectively shutting down the power supply to portions involved with the function of the communication portion 114, it is possible to stop the function of the communication portion 114 in a more reliable manner.

As described above, since the portable information device 110 of the embodiment is provided with the piezoelectric vibrator 1 with improved quality, it is also possible to similarly improve the quality of the portable information device itself. In addition to this, it is possible to display stable and highly accurate clock information over a long period of time.

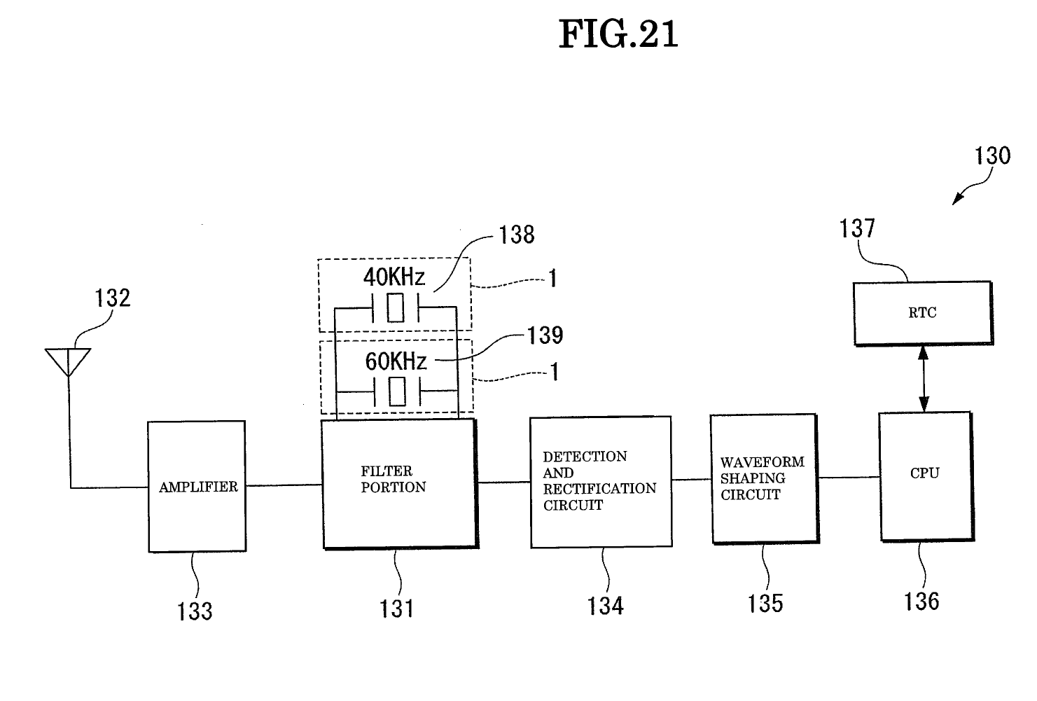

Next, one embodiment of a radio timepiece according to the invention will be described with reference to FIG. 21.

A radio timepiece 130 of the embodiment is provided with the piezoelectric vibrator 1 that is electrically connected to a filter portion 131 as shown in FIG. 21, and is a timepiece that has a function of receiving a standard wave including clock information, and a function of automatically correcting the standard wave to a correct time and displaying it.

In Japan, transmitting stations (transmitter stations) for transmitting standard waves are located in Fukushima prefecture (40 kHz) and Saga prefecture (60 kHz), and transmit standard waves, respectively. A long wave corresponding to 40 kHz or 60 kHz has a property of propagating on the ground surface and also has a property of propagating while being reflected by an ionized layer and the ground surface. Accordingly, the propagation range is wide and the above-mentioned two transmitting stations cover the entire area of Japan.

### (Radio Timepiece)

Hereinafter, a functional structure of the radio timepiece 130 will be described in detail.

An antenna 132 receives a standard wave that is a long wave of 40 kHz or 60 kHz. The standard wave, which is a long wave, is a wave that is obtained by performing AM modulation of time information, which is called a time code, on a carrier wave of 40 kHz or 60 kHz. The received standard wave, which is a long wave, is amplified by an amplifier 133, and is filtered and tuned by the filter portion 131 having a plurality of the piezoelectric vibrators 1.

The piezoelectric vibrators 1 of the embodiment are respectively provided with crystal oscillator portions 138, 139 having resonance frequencies of 40 kHz and 60 kHz, which are the same as the above-described carrier frequencies.

Further, the filtered signal with a predetermined frequency is detected and demodulated by a detection and rectification circuit 134. Then, the time code is taken out through a waveform shaping circuit 135 and is counted by a CPU 136. The CPU 136 reads information of a current year, cumulative days, a day of the week, a time of day, and the like. The read information is reflected on an RTC 137 and correct time information is displayed.

Since the carrier wave has a frequency of 40 kHz or 60 kHz, the above-described oscillator having a tuning-fork type structure is preferably used as the crystal oscillator portions 138, 139.

Note that, although the above-described explanation is made using an example in Japan, the frequencies of long wave standard waves are different in overseas countries. For example, the standard wave with a frequency of 77.5 kHz is used in Germany. Accordingly, when the radio timepiece 130 that is also compatible in overseas countries is incorporated into a portable device, the piezoelectric vibrator 1 having a frequency different from the frequency used in Japan is necessary.

As described above, since the radio timepiece 130 of the embodiment is provided with the piezoelectric vibrator 1 with improved quality, it is also possible to similarly improve the quality of the radio timepiece itself. In addition to this, it is possible to count time stably and highly accurately over a long period of time.

Hereinabove, the embodiment of the invention is described in detail with reference to the drawings. However, specific structures are not limited to the embodiment, and design modifications and the like that do not depart from the spirit of the invention are also included.

For example, although in the above-described embodiment, the piezoelectric vibrating reed 5 of a tuning-fork type is described as an example, it is not limited to the tuning-fork type. For example, a thickness shear vibrating reed or an AT vibrating reed may be mounted in the cavity, and when these vibrating reeds are electrically connected to the external electrodes, the through electrodes may be formed using the above-described method.

Further, in the above-described embodiment, the description is made for the two-layer structure type in which the piezoelectric vibrating reed 5 is housed in the cavity C formed between the base substrate 2 and the lid substrate 3. However, without being limited to this, a three-layer structure type can also be adopted in which the piezoelectric substrate having the piezoelectric vibrating reed 5 formed thereon is bonded to be sandwiched from above and below by the base substrate 2 and the lid substrate 3.

Further, in the above-described embodiment, the case is described in which the glass frit 32a, serving as a filler, is filled between the core portions 31 and the through holes 21, 22. However, without being limited to this, a conductive filler may be filled in the through holes 21, 22 and the conductive filler itself may form through electrodes. As this type of filler, a filler including fine metal particles and a plurality of glass beads, or the above-described conductive paste can be used.

Further, the through holes 21, 22 do not necessarily have a tapered shape, and they may be cylindrical through holes that straightly pass through the base substrate 2.

It is possible to reduce variations in a finish thickness in a surface direction of a glass substrate and to maintain airtightness in a cavity.

What is claimed is:

1. A glass substrate polishing method for polishing a glass substrate using a polishing device, the glass substrate polishing method being characterized in that
the polishing device comprises a surface plate that is rotationally driven around a first central axis, a plate that is rotatable around a second central axis eccentric from the first central axis and presses the glass substrate toward the surface plate, and a work holder that is formed on the plate and restricts movement of the glass substrate in a surface direction while holding the glass substrate in a state in which a central axis of the glass substrate is eccentric from the second central axis, and in that
the glass substrate is polished by rotating the surface plate while the glass substrate is rotatably held in the work holder in a state in which an abrasive is interposed between the glass substrate and the surface plate.

2. The glass substrate polishing method according to claim 1, characterized in that
one surface of the glass substrate is polished such that a recessed portion formed in another surface of the glass substrate is penetrated, and a through hole is formed in the glass substrate.

3. The glass substrate polishing method according to claim 1, characterized in that
a restricting member, which restricts a polishing amount of the glass substrate, is arranged on the plate in a standing condition toward the surface plate.

4. The glass substrate polishing method according to claim 3, characterized in that
when a finish thickness of the glass substrate is denoted by T and a maximum particle diameter of the abrasive is denoted by D, a height H of the restricting member is set to T+2D.

5. The glass substrate polishing method according to claim 1, characterized in that
a plurality of the work holders are formed on the plate, and a plurality of the plates are disposed along a circumferential direction of the surface plate.

6. A package manufacturing method capable of enclosing an electronic component in a cavity formed between a plurality of substrates that are bonded to each other, the package manufacturing method being characterized by comprising:
a through hole forming step of arranging through electrodes that penetrate a first substrate among the plurality of substrates in a thickness direction and conduct a current between an inside of the cavity and an outside of the package, wherein
in the through hole forming step, through holes are formed in the first substrate made of a glass material using the glass substrate polishing method according to claim 1.

7. A piezoelectric vibrator characterized by being manufactured using the package manufacturing method according to claim 6.

8. An oscillator, characterized in that
the piezoelectric vibrator according to claim 7 is electrically connected to an integrated circuit as an oscillation element.

9. An electronic device, characterized in that
the piezoelectric vibrator according to claim 7 is electrically connected to a time measuring portion.

10. A radio timepiece, characterized in that
the piezoelectric vibrator according to claim 7 is electrically connected to a filter portion.
